(19) United States
(12) Patent Application Publication
(10) Pub. No.: US 2007/0075042 A1
(43) Pub. Date: Apr. 5, 2007

(54) Stabilizer-Fenton's reaction metal-vinyl pyridine polymer-surface-modified chemical mechanical planarization composition and associated method

(76) Inventors: Junaid Ahmed Siddiqui, Richmond, VA (US); Timothy Frederick Compton, Casa Grande, AZ (US); Daniel Hernandez Castillo II, Laveen, AZ (US); Bin Hu, Chandler, AZ (US)

Correspondence Address: AIR PRODUCTS AND CHEMICALS, INC.;PATENT DEPARTMENT, 7201 HAMILTON BOULEVARD, ALLENTOWN, PA, 181951501, US

(21) Appl. No.: 11/516,002

(22) Filed: Sep. 5, 2006

Related U.S. Application Data
(60) Provisional application No. 60/723,822, filed on Oct. 5, 2005.

(51) Int. Cl. C09K 13/00; C03C 15/00; B44C 1/22; H01L 21/302; C23F 1/00

(52) U.S. Cl. 216/89; 438/692; 216/88; 252/79.1

(57) ABSTRACT

A composition and an associated method for chemical mechanical planarization (or other polishing) are described. The composition includes a stabilizer-metal-vinyl pyridine polymer surface-modified colloidal abrasive (e.g., silica) and an oxidizing agent (e.g., hydrogen peroxide), where the metal is a Fenton's reaction metal. The method includes applying the composition to a substrate to be polished (e.g., chemical-mechanical polishing (CMP)), such as substrates containing tungsten or copper and dielectrics layers that being subjected to tungsten or copper CMP for planarization.

### CROSS-REFERENCE TO RELATED APPLICATIONS

This application claims benefit of U.S. Provisional Application No. 60/723,822, filed Oct. 05, 2005. The disclosure of this provisional application is hereby incorporated by reference.

### FIELD OF THE INVENTION

This invention relates to an improved composition and method for the chemical mechanical polishing or planarization of semiconductor wafers. More particularly, it relates to such a composition and method tailored to meet more stringent requirements of advanced integrated circuit fabrication.

The present invention pertains to a stabilizer-Fenton's reaction metal-vinyl pyridine polymer (e.g., a boron-iron-poly(vinyl pyridine)) surface-modified colloidal abrasive polishing composition and associated method of using this composition, particularly for chemical mechanical planarization (CMP, also known as chemical mechanical polishing), wherein the slurry comprises a stabilizer-Fenton's reaction metal-vinyl pyridine polymer surface-modified colloidal abrasive and an oxidizing agent. The present invention particularly relates to a composition for polishing substrates comprising at least copper or tungsten and at least one dielectric material using a chemical-mechanical polishing system comprising boron-metal-polyvinylpyridine surface-modified colloidal silica and per-compound oxidizing agents, wherein the metal is a Fenton's reaction metal.

### BACKGROUND OF THE INVENTION

CMP for planarization of semiconductor substrates is now widely known to those skilled in the art and has been described in numerous patents and open literature publications. Some introductory references on CMP are as follows: “Polishing Surfaces for Integrated Circuits”, by B. L. Mueller and J. S. Steckenrider, Chemtech, February, 1998, pp. 38-46; H. Landis et al., Thin Solids Films, 220 (1992), page 1; and “Chemical-Mechanical Polish” by G. B. Shinn et al., Chapter 15, pages 415-460, in Handbook of Semiconductor Manufacturing Technology, editors: Y. Nishi and R. Doering, Marcel Dekker, New York City (2000).

In a typical CMP process, a substrate (e.g., a wafer) is placed in contact with a rotating polishing pad attached to a platen. A CMP slurry, typically an abrasive and chemically reactive mixture, is supplied to the pad during CMP processing of the substrate. During the CMP process, the pad (fixed to the platen) and substrate are rotated while a wafer carrier system or polishing head applies pressure (downward force) against the substrate. The slurry accomplishes the planarization (polishing) process by chemically and mechanically interacting with the substrate film being planarized due to the effect of the rotational movement of the pad relative to the substrate. Polishing is continued in this manner until the desired film on the substrate is removed with the usual objective being to effectively planarize the substrate. Typically metal CMP slurries contain an abrasive material, such as silica or alumina, suspended in an oxidizing, aqueous medium.

Silicon based semiconductor devices, such as integrated circuits (ICs), typically include a dielectric layer. Multilevel circuit traces, typically formed from aluminum or an aluminum alloy or copper, are patterned onto the dielectric layer substrate. These are numerous types of layers that can be polished by CMP, for example, silicon nitride, interlayer dielectrics (ILD) such as silicon oxide and low-k films including carbon-doped oxides; metal layers such as tungsten, copper, aluminum, etc., which are used to connect the active devices; barrier layer materials such as titanium, titanium nitride, tantalum, tantalum nitride, noble metals, etc.

CMP processing is often employed in semiconductor manufacturing to remove excess metal at different stages. Various metals and metal alloys have been used at different stages of semiconductor manufacturing, including tungsten, aluminum, copper, tantalum, tantalum nitride, titanium, titanium nitride, ruthenium, platinum, iridium, and combinations thereof. For example, one way to fabricate a multilevel copper interconnect or planar copper circuit traces on a dielectric substrate is referred to as the damascene process.

Surface modification of the abrasive is known. Colloidal silica, for example, has been modified with various metallic compounds as disclosed in U.S. Pat. Nos. 3,252,917, 3,620,978 and 3,745,126; EP Patent Publication 1 000 995; and also in the book entitled “The Chemistry of Silica”, R. K. ller, Wiley Interscience (1979), pages 410-411.

Colloidal silica has been stabilized with boric acid as disclosed in U.S. Pat. No. 2,630,410. See also co-owned U.S. Pat. No. 6,743,267, the disclosure of which is incorporated herein by reference thereto, which discloses a composition and method for chemical-mechanical planarization comprising a surface-modified colloidal abrasive (e.g., ceria or silica) that has been modified with boron-containing compound(s).

During the fabrication of integrated circuit (IC) devices, polishing slurries for chemical mechanical planarization of tungsten must meet several criteria such as: high tungsten removal rates; minimal erosion of dielectric layers; high tungsten-to-dielectric layer removal rate selectivity; low tungsten static etch rates; and, low contamination from catalysts which are typically multivalent soluble cations such as iron salts.

In order to achieve fast tungsten or copper removal rates, the use of oxidants and co-oxidants have been reported in the CMP patent literature. For tungsten CMP, oxidants such as periodic acid, potassium iodate, ferric nitrate, and hydrogen peroxide are commonly used. For copper CMP, hydrogen peroxide and hydroxylamine are commonly used oxidants. Of all the oxidants in commercial use, hydrogen peroxide is low cost, and it is benign from the standpoint of product stewardship, as the byproduct is water. However hydrogen peroxide is a poor oxidant for tungsten as it reacts very slowly, so an additive that can catalyze the reaction between tungsten and hydrogen peroxide during CMP is highly desirable. There have been a number of disclosures relating to soluble metal catalysts. See, for example, U.S. Pat. No. 5,958,288, which describes the use of soluble metal co-catalysts for activating hydrogen peroxide for the planarization of tungsten. See also Patent No. SU 1629353, which discloses a composition and method for CMP of aluminum alloys, wherein soluble iron (iron chloride) is used to activate sodium perborate in the presence of diethyldithiophosphoric acid and ninhydrin. Patent Publication No. WO 99/53532 recited as one embodiment of the invention a CMP slurry comprising water, abrasive particles, and an oxidizing solution comprising a soluble peroxide, an amino acid, and one or more metals and/or compounds containing metals selected from the group consisting of chromium, cobalt, copper, iron, lead, nickel, palladium, rhodium, samarium, and scandium, with copper being preferred. This application recites that “the use of metals and/or compounds containing metals in combination with water soluble peroxide and amino acid results in the accelerated generation of hydroxyl radicals and yields a much more effective polishing composition.

While the use of soluble metal co-catalysts increases the speed at which hydrogen peroxide reacts with copper or tungsten, they also require CMP slurries with large concentrations of dissolved, ionic metallic components. As a result, the polished substrates can become contaminated by the adsorption of charged species from the metal co-catalysts. These species can migrate and change the electrical properties of the devices, for example at gates and contacts, and change the effective dielectric properties of dielectric layers. These changes may reduce the reliability of the integrated circuits with time. Therefore, it is desirable to expose the wafer only to high purity chemicals with very low concentrations of mobile metallic ions. Accordingly, it is desired to provide a polishing composition that does not contain large concentrations of dissolved metal ions. It is further desired to provide a polishing composition particularly suitable for conducting metal CMP, such as copper or tungsten CMP, which composition contains a Fenton's reaction metal capable of initiating a Fenton's reaction with a per-compound oxidizing agents, preferably hydrogen peroxide, to provide very high tungsten polishing rates, while reducing metal ion contamination of the polished dielectric substrate. The present invention provides a solution to this requirement.

All references cited herein are incorporated herein by reference in their entireties.

### BRIEF SUMMARY OF THE INVENTION

In one embodiment it has been found that CMP polishing compositions comprising: A) a boron surface-modified abrasive modified with a Fenton's reaction metal coated on the surface thereof, e.g., a boron-iron-surface-modified silica abrasive described herein; B) the abrasive modified further with low levels of a vinylpyridine polymer coated on the surface thereof, e.g., a boron-iron-polyvinylpyridine-surface-modified silica abrasive described herein; and C) a per-compound oxidizing agent that produces free radicals when contacted by said coated abrasive, e.g., a peroxide-type oxidizing agent, preferably hydrogen peroxide; are effective in reducing iron ion contamination on the surface of wafers polished with these polishing compositions, in comparison otherwise to identical compositions without vinylpyridine polymer being present. Additionally, it has been found that such CMP polishing compositions can provide increased tungsten polishing rates and decreased dielectric oxide polishing rates. By low levels of a vinylpyridine polymer we mean less than 0.1 weight percent, preferably less than 0.05 weight percent, for example less than 0.025 weight percent, or alternately between about 10 ppm and about 200 ppm at point of use. A specific preferred embodiment comprises between about 10 ppm and about 100 ppm of a vinylpyridine polymer in a slurry comprising an abrasive modified with a Fenton's reaction metal coated on the surface thereof, e.g., a boron-iron-surface-modified silica, where the total amount of iron in the slurry at point of use is between about 1 ppm and about 25 ppm, preferably between about 3 ppm and about 15 ppm, for example between about 4 ppm and about 10 ppm iron, disposed on the between about 0.5 weight percent and about 3 weight percent, for example 1 weight percent to about 2 weight percent of abrasive, e.g., boron-surface-modified silica. The iron ion contamination is reduced due to the complexation of vinylpyridine polymer with iron ions to form water soluble iron-vinylpyridine polymer salts; these water soluble salts are removed easily from the wafer surface during polishing and reduce the need for additional cleaning or buffing steps during the fabrication of semiconductor devices.

In another embodiment it has been found that CMP polishing compositions comprising: A) boron-surface modified colloidal abrasive modified with a Fenton's reaction metal coated on the surface thereof, e.g., a boron-iron-surface-modified colloidal silica abrasive described herein; B) the abrasive modified further with low levels of a vinylpyridine polymer coated on the surface thereof, e.g., a boron-iron-polyvinylpyridine-surface-modified silica abrasive described herein; C) a per-compound oxidizing agent that produces free radicals when contacted by said coated abrasive, e.g., a peroxide-type oxidizing agent, preferably hydrogen peroxide; and D) a fumed silica co-abrasive; can provide increased tungsten polishing rates and decreased dielectric oxide polishing rates. By low levels of a vinylpyridine polymer we mean less than 0.1 weight percent at point of use. Additionally, it has been found that such CMP polishing compositions are effective in reducing iron ion contamination on the polished surface of wafers, in comparison otherwise to identical compositions without vinylpyridine polymer being present.

In one embodiment, the invention is a chemical-mechanical polishing composition for substrates containing at least one metal and at least one dielectric material comprising:
a) a stabilizer-Fenton's reaction metal-vinyl pyridine polymer-surface-modified abrasive; and
b) an oxidizing agent.

Still further provided is a method for polishing a surface of a substrate, said method comprising applying the composition of the invention to the surface of the substrate to polish the surface of the substrate, wherein the substrate comprises at least copper or tungsten and at least one dielectric material. In an embodiment, the invention is a method of polishing comprising the steps of:
A) placing a substrate in contact with a polishing pad;
B) delivering a polishing composition comprising:
   a) a stabilizer-Fenton's reaction metal-vinyl pyridine polymer-surface-modified abrasive; and
   b) an oxidizing agent; and
C) polishing the substrate with the polishing composition.

### DETAILED DESCRIPTION OF THE INVENTION

The invention is in a broad sense the inclusion of small quantities of vinylpyridine polymers, which are effective to reduce the amount of surface contamination from transition metal ions such as Fenton's reaction metals and also to suppress dielectric removal rates, when the slurry comprises an abrasive having associated on the surface thereof stabilizers and Fenton's reaction metals, preferably wherein the Fenton's reaction metal is iron ions absorbed on the surface thereof, and an oxidizer which produces free radicals when contacted by said Fenton's reaction metals. The low levels of vinylpyridine polymer additives are preferably absorbed on the surface of the stabilizer-Fenton's-reaction-metal-surface-modified abrasive particle, to form a stabilizer-Fenton's-reaction-metal-polyvinylpyridine-surface-modified abrasive described herein.

In one embodiment it has been found that CMP polishing compositions comprising: A) a boron-surface modified abrasive modified with a Fenton's reaction metal coated on the surface thereof, e.g., a boron-iron-surface-modified silica abrasive described herein; B) the abrasive modified further with low levels of a vinylpyridine polymer coated on the surface thereof, e.g., a boron-iron-polyvinylpyridine-surface-modified silica abrasive described herein; and C) a per-compound oxidizing agent that produces free radicals when contacted by said coated abrasive, e.g., a peroxide-type oxidizing agent, preferably hydrogen peroxide; are effective in reducing iron ion contamination on the surface of wafers polished with these polishing compositions, in comparison otherwise to identical compositions without vinylpyridine polymer being present. Additionally, it has been found that such CMP polishing compositions can provide increased tungsten polishing rates and decreased dielectric oxide polishing rates. By low levels of a vinylpyridine polymer we mean less than 0.1 weight percent, preferably less than 0.05 weight percent, for example less than 0.025 weight percent, or alternately between about 10 ppm and about 200 ppm at point of use. A specific preferred embodiment comprises between about 10 ppm and about 100 ppm of a vinylpyridine polymer in a slurry comprising an abrasive modified with a Fenton's reaction metal coated on the surface thereof, e.g., a boron-iron-surface-modified silica, where the total amount of iron in the slurry at point of use is between about 1 ppm and about 25 ppm, preferably between about 3 ppm and about 15 ppm, for example between about 4 ppm and about 10 ppm iron, disposed on the between about 0.5 weight percent and about 3 weight percent, for example 1 weight percent to about 2 weight percent of abrasive, e.g., boron-surface-modified silica. The iron ion contamination is reduced due to the complexation of vinylpyridine polymer with iron ions to form water soluble iron-vinylpyridine polymer salts; these water soluble salts are removed easily from the wafer surface during polishing and reduces the need for additional cleaning or buffing steps during the fabrication of semiconductor devices.

In another embodiment it has been found that CMP polishing compositions comprising: A) boron-surface modified colloidal abrasive modified with a Fenton's reaction metal coated on the surface thereof, e.g., a boron-iron-surface-modified colloidal silica abrasive described herein; B) the abrasive modified further with low levels of a vinylpyridine polymer coated on the surface thereof, e.g., a boron-iron-polyvinylpyridine-surface-modified silica abrasive described herein; C) a per-compound oxidizing agent that produces free radicals when contacted by said coated abrasive, e.g., a peroxide-type oxidizing agent, preferably hydrogen peroxide; and D) a fumed silica co-abrasive; can provide increased tungsten polishing rates and decreased dielectric oxide polishing rates. By low levels of a vinylpyridine polymer we mean less than 0.1 weight percent at point of use. Additionally, it has been found that such CMP polishing compositions are effective in reducing iron ion contamination on the polished surface of wafers, in comparison otherwise to identical compositions without vinylpyridine polymer being present.

This invention relates to polyvinylpyridine or vinylpyridine polymer additives, preferably vinylpyridine polymer additives such as poly(2-vinylpyridine) or poly(4-vinylpyridine), which are added to slurries comprising a Fenton's reaction metal disposed and preferably absorbed on the surface of an abrasive surface-modified with a stabilizer, i.e., a stabilizer-Fenton's-reaction-metal-surface-modified abrasive particle. The low levels of vinylpyridine polymer additives are preferably absorbed on the surface of the stabilizer-Fenton's-reaction-metal-surface-modified abrasive particle, to form a stabilizer-Fenton's-reaction-metal-polyvinylpyridine-surface-modified abrasive described herein.

By “Fenton's reaction metal” we mean those metal ions which react with certain oxidizers, particularly with peroxides such as hydrogen peroxide, to produce oxygen-containing free radicals such as a hydroxyl radical. Depending on the slurry (and oxidizer) used, suitable metals may include one or more of Cu, Fe, Mn, Ti, W, Ag, and V. The Fenton's reaction metal must be active, and is preferably not in the form of an oxide, but is rather in the form of an ion absorbed onto the surface of the abrasive. Generally, the two Fenton's reaction metals most useful for modifying the surface of an abrasive are iron and/or copper, with iron being preferred.

By abrasive we mean a member selected from the group consisting of one or more of alumina, titania, zirconia, germania, silica, ceria, spinels, iron oxides, copper oxides, and/or any other solid materials capable of abrading a surface and of maintaining active Fenton's reaction metal absorbed on the surface thereof. Silica is the preferred abrasive. The abrasive may be produced by any technique known to those skilled in the art. Due to stringent purity requirements in the integrated circuit industry, the preferred abrasive should be of a high purity. High purity means that the total impurity content, from sources such as raw material impurities and trace processing contaminants, is typically less than 1% and preferably less than 0.01% (i.e., 100 ppm). Of course, this is the purity before the surface of the abrasive is modified with a Fenton's reaction metal and also a stabilizer. The surface-modified particle may be less 99% pure, depending on the size of the particle and on the density of the surface-modifying components disposed on the particles. The abrasive may consist of discrete, individual particles having discrete particle diameters from 5 nanometers to 5 microns, preferably 5 nanometers to 500 nanometers, more preferably from 10 nanometers to 100 nanometers. By the term “diameter” we mean the mean particle diameter as determined by the average equivalent spherical diameter when using transmission electron microscopy (TEM) image analysis, i.e., based on the area of the particles which is converted to a circle and then the diameter is determined. Generally, the particle size is not important, except that larger particles provide faster rates but higher defect levels than do smaller particles. The particles are advantageously round (spherical) or oval. Colloidal silica is the most preferred abrasive.

Advantageously the surface of the abrasive is at least partially modified with a stabilizer. The term “stabilizer” means an agent effective to help maintain the abrasive as a sol in an aqueous medium. Suitable stabilizers include metal ions and borderline metal ions absorbed onto the surface of the abrasive, such as, boron, aluminum, tungsten and titanium, with boron being most preferred. The most preferred stabilizer is boron, advantageously provided from boric acid, and we call a particle so treated a boron-surface-modified abrasive.

The most preferred abrasive is an boron-iron-surface-modified colloidal silica having an average diameter of between 10 nanometers and about 130 nanometers, for example between about 40 nanometers and about 80 nanometers.

The molar ratio of Fenton's reaction metals to stabilizer can vary depending upon the substrate and the nature and quantity of any oxidizing agent being used. Similarly, the molar ratio of Fenton's reaction metal to abrasive can also vary depending upon conditions and desired results. For example, the molar ratio of Fenton's reaction metals to stabilizer preferably ranges from 1:1 to 1:10 and the molar ratio of Fenton's reaction metals to abrasive preferably ranges from 1:1 to 1:10. In certain embodiments, the molar ratio of stabilizer to abrasive ranges from 10:1 to 1:10.

The amount of surface-modification of the colloidal abrasive with stabilizer depends upon the average size of the colloidal abrasive particles. Colloidal abrasive particles that are smaller and which consequently have less surface area generally require higher relative amounts of stabilizer than do larger particles, which have more surface area. The surface coverage of the surface modified abrasive can be characterized using zeta potential measurement. For example, the amount of surface coverage of boric acid on the silica surface can be measured using an AcoustoSizer II Flow-through System instrument, manufactured by Colloidal Dynamics Inc. The AcoustoSizer II Flow-through System instrument measures the zeta potential (surface charge) of the surface modified silica particles. During the preparation of boron surface-modified silica, boric acid is added to the deionized silica particles, which changes the zeta potential of the silica particle surface. After reaching the full surface coverage, there is no change in the zeta potential of the surface modified silica with continued addition of boric acid. From this titration curve of zeta potential as a function of grams of boric acid to a given amount of silica, it is possible to measure the percent surface coverage of boric acid on the silica surface. After completing the reaction with boric acid, the surface coverage achieved by reacting the boron surface-modified sol with a Fenton's reaction metal salt can also be determined from the zeta potential. The pH and zeta potential can be controlled by changing the concentration of boric acid or Fenton's reaction metal, for example ferric nitrate, absorbed on the surface of the silica. It is preferred that at least 1%, more preferably 40-95% or 80-99% of available surface sites on the abrasive be occupied by the stabilizer and the Fenton's reaction metal. The number of sites occupied by stabilizer and by Fenton's reaction metal need not be equal. The percentage of surface sites covered on an abrasive in a composition of this invention can range up to 100%. A particle may have between 90% to 99% or more of surface sites occupied by a stabilizer, and still absorb some iron. It is not known if the stabilizer and the iron interact to occupy a single active site.

In another embodiment, the composition of the invention also comprises a fumed abrasive as a co-abrasive to a colloidal stabilizer-Fenton's-reaction-metal-polyvinylpyridine-surface-modified abrasive. The co-abrasive consists of a fumed abrasive, with fumed silica preferred, where the metal oxide aggregates and particles have a size distribution less than about 1.0 micron, a mean diameter less than about 0.4 micron and a force sufficient to repel and overcome the van der Waals forces between abrasive aggregates and particles themselves. By force is meant that either the surface potential or the hydration force of the metal oxide particles must be sufficient to repel and overcome the van der Waals attractive forces between the particles.

The per compound oxidizing agent is advantageously a monopersulfate, a persulfate, a peroxide, a periodate, a peroxy or mixtures thereof. More preferably, the per compound oxidizing agent comprises at least one of periodic acid, hydrogen peroxide and urea-hydrogen peroxide, with hydrogen peroxide being most preferred

Generally, the slurry comprises between 0.1 weight percent and 10 weight percent, typically between 1 weight percent and 5 weight percent, of per-compound oxidizer, e.g., hydrogen peroxide, between 0.1 weight percent and 6 weight percent, typically between 0.5 weight percent and 3 weight percent, of stabilizer-Fenton's-reaction-metal-surface-modified abrasive. The amount of surface-absorbed Fenton's reaction metal, if it is iron, in the slurry advantageously is between about 1 ppm to about 25 ppm, more advantageously between about 3 ppm and about 15 ppm, and typically between about 4 ppm and about 10 ppm. Copper would generally require more, e.g. more than twice the amount as does iron. Other Fenton's reaction metals would require even greater amounts to obtain the same activity. The amount of vinylpyridine polymer is advantageously between about 0.001 weight percent and 0.1 weight percent, preferably between about 10 ppm and about 200 ppm, for example between about 10 ppm and about 100 ppm. The “amount of vinylpyridine polymer can be expressed as percent by weight of boron-metal-surface-modified silica”, by dividing the weight percent vinylpyridine polymer by the weight percent boron-metal-surface-modified silica. The “amount of vinylpyridine polymer expressed as percent by weight of boron-iron-surface-modified silica” in the slurry advantageously is between about 0.1 to about 10.0, more advantageously between about 0.3 and about 5.0, and typically between about 0.3 and about 0.5.

The medium is preferably aqueous and more preferably deionized water.

Other well known polishing slurry additives may be incorporated alone or in combination into the CMP slurry of this invention. A non-inclusive list includes agents to stabilize the oxidizer in the presence of the a metal complex, inorganic acids, organic acids, corrosion inhibitors, chelating agents, surfactants, alkyl ammonium salts or hydroxides, and dispersing agents.

The pH of the compositions of this invention is not limited and can be chosen to be that corresponding to an acidic, a basic, or a neutral value. The pH of the composition is advantageously between about 2 and about 8.

The slurry may further comprise between 0.001 weight percent and about 0.2 weight percent of one or more of phosphoric acid, phosphonic acid, polyphosphoric acids, pyrophosphoric acids, polyphosphonic acids, or metal-free salts thereof.

A preferred slurry comprises 0.5 weight percent to 3 weight percent, preferably 1 weight percent to 2 weight percent, of boron-iron-surface-modified colloidal silica (having 1 ppm to 25 ppm, preferably 3 ppm to 15 ppm iron, based on the weight of the slurry disposed on the silica); a minor amount, for example between 0.001 weight percent and 0.1 weight percent of an inorganic acid, for example nitric acid; from about 0.005 weight percent to about 0.2 weight percent, preferably from about 10 ppm to about 200 ppm of vinylpyridine polymer, about 1 weight percent to about 8 weight percent, preferably between about 3 weight percent and about 5 weight percent, of hydrogen peroxide, and a balance water.

This invention provides compositions and methods that are particularly useful for CMP of metal-containing substrates, including tungsten-containing substrates, copper-containing substrates, titanium-containing substrates, titanium-nitride containing substrates, tantalum-containing substrates, tantalum-nitride containing substrates, and other substrates associated with integrated circuits, thin films, semiconductors, and wafers. Traditional CMP procedures can be utilized, including adhering some or all of the abrasive material onto the polishing pad. The associated methods of this invention comprise the use of the aforementioned compositions for polishing substrates. Typically, a substrate (e.g., a wafer) is placed face-down on a polishing pad which is fixedly attached to a rotatable table of a polisher. In this manner, the substrate to be polished is placed in direct contact with the polishing pad. A wafer carrier system or polishing head is used to hold the substrate in place and to apply a downward pressure against the backside of the substrate during CMP processing while the table and the pad are rotated. The polishing composition (e.g., CMP slurry) is applied (usually continuously) on the pad during CMP processing to effect the removal of material to (at least partially) planarize the substrate.

Advantageously, if used to polish tungsten, the tungsten removal rate is greater than 300 Å/min, preferably greater than 4000 Å/min, and is typically between 5000 and 7000 Å/min. As is known in the art, the removal rate can be varied by a number of factor. The composition and associated methods of this invention are particularly useful and preferred for tungsten CMP and afford very high selectivities for removal of tungsten in relation to dielectric (as illustrated in the examples). In certain embodiments, the selectivity for removal of tungsten relative to removal of the dielectric from the substrate is at least 15:1, typically at least 20:1, and advantageously at least 30:1. Selectivity of tungsten to titanium nitride is at least 3: 1, typically at least 4:1, and advantageously at least 5:1.

While not being bound by any particular theory, the inventor(s) believes that the following considerations may explain why a polishing composition comprising: A) a boron-surface modified abrasive modified with a Fenton's reaction metal coated on the surface thereof, e.g., a boron-iron-surface-modified silica abrasive described herein; B) the abrasive modified further with low levels of a vinylpyridine polymer coated on the surface thereof, e.g., a boron-iron-polyvinylpyridine-surface-modified silica abrasive described herein; and C) a per-compound oxidizing agent that produces free radicals when contacted by said coated abrasive, e.g., a peroxide-type oxidizing agent, preferably hydrogen peroxide; are effective in reducing iron ion contamination on the surface of wafers polished with these polishing compositions in CMP processing and exhibits increased tungsten polishing rates with decreased dielectric oxide polishing rates. The surface modification of the boron-iron-surface-modified silica with vinylpyridine polymer can prevent the migration of iron ions into the solution, which reduces iron ion contamination on the wafer surface. Furthermore, if iron ions are released during the polishing of a wafer as a result of particle collision with the wafer surface, the vinylpyridine polymer can form soluble complexes with iron ions which can then be readily removed from the system during the wafer processing, hence resulting in low iron contamination on the polished wafer surface. In addition to reducing iron contamination on the wafer surface, as the concentration of vinylpyridine polymer increases in the polishing formulation it can reduce dielectric layer removal rates by coating the protonated dielectric oxide layer, in particularly when fumed abrasive is present as a co-abrasive in the slurry.

The present invention is further demonstrated by the examples below.

### GLOSSARY

Exemplary Components (and Equivalents Thereof)

A) Vinylpyridine polymer: The chemical names of various vinylpyridine polymers are summarized below:
2) Poly(2-vinylpyridine) (2PVPY); molecular weight >15,000 Daltons: Sigma-Aldrich, P.O. Box 355, Milwaukee, Wis. 53201.
3) Poly(4-vinylpyridine) (4PVPY); molecular weight>15,000 Daltons: Sigma-Aldrich, P.O. Box 355, Milwaukee, Wis. 53201.
4) REILLINE™ 410 Polymer; Poly(4-vinylpyridine) homopolymer (42-48 weight percent solution in methanol): Reilly Industries, Inc., 300 North Meridian Street, Suite 1500, Indianapolis, Ind. 46204.

B) Other co-additives with vinylpyridine polymers in the polishing compositions:
A list of other additives used in the polishing formulations is summarized below:
1) Aerosil® OX 50 fumed silica: Degussa, Postfach 1345, D-63403, Hanau, Germany.
2) Boron surface-modified colloidal silica (based on Syton® HT50 colloidal silica with average particle diameter of 40 to 55 nanometers): DuPont Air Products NanoMaterials L.L.C., 2507 West Erie Drive, Tempe, Ariz. 85282.
3) Ferric nitrate nonahydrate: Sigma-Aldrich, P.O. Box 355, Milwaukee, Wis. 53201, or Wako Pure Chemical Industries, Ltd., 1-2, Doshomachi 3-Chome, Chuo-ku, Osaka 540-8605, Japan.
4) Hydrogen Peroxide (30 weight % solution): Air Products and Chemicals, Inc., 7201 Hamilton Blvd. Allentown, Pa. 18195-1501, or Wako Pure Chemical Industries, Ltd., 1-2, Doshomachi 3-Chome, Chuo-ku, Osaka 540-8605, Japan.
5) Nitric acid (70 percent solution): Sigma-Aldrich, P.O. Box 355, Milwaukee, Wis. 53201, or Hayashi Pure Chemical Ind., Co., Ltd, 3-2-12, Uchihirano-machi, Chuo-ku, Osaka-shi, Osaka, Japan.
6) Sodium dodecylsulfate: Sigma-Aldrich, P.O. Box 355, Milwaukee, Wis. 53201.
7) Surfynol® 104—This commercial product is 2,4,7,9-tetramethyl-5-decyn-4,7-diol: Air Products and Chemicals, Inc., Allentown, Pa. 18194 (added as Surfynol® 104E, a 50:50 mixture of 2,4,7,9-tetramethyl-5-decyn-4,7-diol in ethylene glycol for ease of handling during the preparation of CMP slurry formulations).

C) General
PETEOS Plasma enhanced deposition of tetraethoxy silane; a dielectric oxide layer.
Blanket Wafers: Blanket wafers are those that have typically one type of surface prepared for polishing experiments.
Parameters
   Å: angstrom(s)—a unit of length
   CMP: chemical mechanical planarization, or chemical mechanical polishing
   min: minute(s)
   ml: milliliter(s)
   mV: millivolt(s)
   psi: pounds per square inch
   rpm: revolution(s) per minute
W:PETEOS Sel Tungsten:PETEOS Selectivity—the ratio of the amount of tungsten removed to the amount of PETEOS removed during CMP experiments using blanket wafers under identical conditions.
W:TOx Sel Tungsten:thermal oxide Selectivity—the ratio of the amount of tungsten removed to the amount of thermal oxide removed during CMP experiments using blanket wafers under identical conditions.

### EXAMPLES

The invention will be illustrated in more detail with reference to the following Examples, but it should be understood that the present invention is not deemed to be limited thereto.

All percentages are weight percentages and all temperatures are degrees Celsius unless otherwise indicated.
Zeta Potential Measurements

Zeta potential measurements were made using an AcoustoSizer II Flow-through System instrument, manufactured by Colloidal Dynamics Inc., 11 Knight Street, Building E18, Warwick, R.I. 02886. This instrument measures the zeta potential (surface charge) of colloidal particles, such as unmodified silica particles and surface-modified colloidal silica particles.

Preparation of Boron Surface-Modified Colloidal Silica

This procedure describes the preparation of boron surface-modified silica with colloidal silica particles having an average particle diameter of 40 to 55 nanometers.

Approximately 1 kg of AMBERLITE IR-120 ion exchange resin (Rohm and Haas Company, Philadelphia, Pa.) was washed with 1 liter of 20% sulfuric acid solution. The mixture was stirred and the resin was allowed to settle. The aqueous layer was decanted and washed with 10 liters of deionized water. The mixture was again allowed to settle and then the aqueous layer was decanted. This procedure was repeated until the decanted water was colorless. This procedure afforded an acidic form of (acid-state) resin.

Syton® HT50 (12 kg, DuPont Air Products NanoMaterials L.L.C., Tempe, Ariz.) was placed in a five-gallon mix tank equipped with an agitator. 2.502 kg of deionized water were added to the tank and the solution was allowed to mix a few minutes. The pH of the solution was measured to be approximately 10.2. With continued pH monitoring, small amounts of acid-state resin were added, while allowing the pH to stabilize in between additions. Additional acid-state resin was added in small portions until the pH had dropped to pH 1.90-2.20. Once this pH limit had been reached and was stable in this range, no further resin additions were made and the mixture was stirred for 1-1.5 hours. Subsequently, the mixture was passed through a 500-mesh screen to remove the resin and afforded deionized Syton® HT50.

A solution of 268 g of boric acid powder (Fisher Scientific, 2000 Park Lane, Pittsburgh, Pa., 15275) in 5.55 kg of deionized water was prepared in a 10 gallon mixing tank equipped with an agitator and a heater by slowly adding the boric acid powder until all had been added to the water and then agitating the mixture for 15 hours and increasing the temperature of the mixture to 55-65° C. Deionized and diluted Syton® HT50 (14.5 kg) was then added to the boric acid solution slowly over about 1.2 hours by adding it at approximately 200 ml/minute and maintaining the temperature greater than 52° C. while agitating the mixture. After this addition was completed, heating at 60° C. and agitation of the mixture were continued for 5.5 hours. The resulting solution was subsequently filtered through a 1-micron filter to afford boron surface-modified colloidal silica.

Preparation of Boron-Iron Surface-Modified Colloidal Silica

This procedure describes the preparation of boron-iron surface-modified silica with colloidal silica particles having an average particle diameter of 40 to 55 nanometers.

Boron surface-modified silica from Example 1 (1000 grams) was transferred to a 4-liter beaker. Under agitation, 5.1 g of ferric nitrate was added to the boron surface-modified silica. The mixture was heated between 45 to 50° C. for 2.8 hours. After heating the mixture, the dispersion was cooled to ambient temperature. The measured zeta potential changed from (negative) −58 mV to (positive) for the boron surface-modified silica +10.2 mV for the boron-iron surface-modified silica. In the boron-iron surface-modified silica, the molar ratio of iron-to-boric acid was 1:43 (or 0.023), and the molar ratio of iron-to-silica was 1:4 (or 0.25). The pH of the slurry was measured as 2.1.

Measurement of Immobilized Iron on the Surface of Boron-Iron Surface-Modified Colloidal Silica

Table 1 is a summary of zeta potential data of boron surface-modified silica and several boron-iron surface-modified colloidal silicas with different concentrations of iron ions immobilized on the boron-iron surface-modified colloidal silica. The boron surface-modified silica was prepared according to the procedure described supra. The boron-iron surface-modified silica were prepared according to the procedure described supra, with varying levels of ferric nitrate. Clearly as the concentration of iron ion increased from 0 ppm to 7.6 ppm, zeta potential increased from (negative) −141 mV (no iron ions) to (negative) −39.3 mV (7.6 ppm iron ions on the surface of the boron-iron surface-modified colloidal silica). Interestingly, a charge reversal occurred on the boron-iron surface-modified colloidal silica as the concentration of iron ions was further increased to 57 ppm, where the zeta potential increased to (positive) +39.9 mV for the boron-iron surface-modified colloidal silica.

TABLE 1
Evidence of Iron Coating on Boron Surface-Modified Silica; Charge Reversal from Anionic
Boron Surface-Modified Silica to Cationic Boron-Iron Surface-Modified Silica.

| | | Boron-iron | Boron-iron | Boron-iron | Boron-iron |
|---|---|---|---|---|---|
| | | surface- | surface- | surface- | surface- |
| | | modified silica | modified silica | modified silica | modified silica |
| | | coated with 3.6 | coated with 5.7 | coated with 7.6 | coated with 57 |
| | Boron surface- | ppm of iron | ppm of iron | ppm of iron | ppm of iron |
| | modified silica | ions | ions | ions | ions |
| Colloidal silica | 1.3 | 1.3 | 1.3 | 1.3 | 1.3 |
| (weight percent) | | | | | |
| Zeta potential of | −141 mV | −92.3 mV | −64.2 mV | −39.3 mV | +39.9 mV |
| colloidal silica | | | | | |

Measurement of Free Iron Ions in the Solution Phase of Boron-Iron Surface-Modified Silica

The concentration of free iron ions in standard aqueous solutions of ferric nitrate were measured using Inductively-Coupled Plasma Mass Spectroscopy (ICPMS). After generating a calibration curve, the aqueous solution phase of a boron-iron surface-modified colloidal silica dispersion was separated from the solid (abrasive) phase, and the solution phase was tested by ICPMS for iron (ferric) ion concentration with a measured value of free iron (ferric) ions less than 100 ppb. the ICPMS data indicates that the iron is predominately immobilized on the surface of the boron-iron surface-modified colloidal silica.

The zeta potential and ICPMS data, as described above, conclusively suggest that iron (ferric) ions readily coat the boron surface-modified silica via an acid-base reaction to produce boron-iron surface-modified silica; ferric ion is a Lewis acid and boron surface-modified silica is a Lewis base.

Addition of Boric Acid-Iron Nitrate Mixture to Deionized Syton® HT50

This procedure describes the preparation of boron-iron surface-modified silica with colloidal silica particles having an average particle diameter of 40 to 55 nanometers.

Syton® HT50 (600 g, supplied by DuPont Air Products NanoMaterials L.L.C.) was deionized at pH 2 according to the procedure described in Example 1, and then transferred to a 4-liter beaker. Under agitation, 400 g of deionized water was added, followed by the addition of a mixture of boric acid (12 g) and ferric nitrate (10.1 g). After the addition of boric acid and ferric nitrate, an additional 278 g of water was added. The mixture was heated between 45 and 50° C. for 2.5 hours. After heating, the mixture was cooled, the molar ratio of iron-to-silica was 1:2 (0.5), the molar ratio of iron-to-boric acid was 2:4.3 (0.47), the pH was 1.67, and the zeta potential was (positive) +16.4 mV.

Preparation of Poly(4-vinylpyridine) (4PVPY) Modified Boron-Iron Surface-Modified Silica

This procedure describes the preparation of poly(4-vinylpyridine) (4PVPY) modified boron-iron surface-modified silica with colloidal silica particles having an average particle diameter of 40 to 55 nanometers.

Boron surface-modified silica (2.0 kg) described supra was transferred to a 25-liter container. Under agitation, 34.06 kg of deionized water was added to the boron surface-modified silica to form 36.06 kg of diluted boron surface-modified silica; solution Part A.

Deionized water (466.5 g) was transferred to a separate 4-liter container and under agitation 7.0 g of 70% nitric acid was added to the deionized water and mixed for 5 minutes. Under agitation, 50.0 g of 4PVPY was added to the nitric acid/deionized water mixture and the contents further agitated for 10 minutes. After completing the addition of 4PVPY, 8.0 g of ferric nitrate nonahydrate was added over a period of 5 minutes to form 531.5 g of acidic poly(4-vinylpyridine); solution Part B.

Under agitation over a period of 5 minutes, the 531.5 g g of solution Part B was added to the solution Part A to obtain the 4PVPY modified boron-iron surface-modified silica particle (36.56 Kg) dispersion. Under agitation, the pH of the mixture was adjusted to 2.8 with 7.6 g of 70% nitric acid, followed by the addition of 3.43 kg of deionized water and agitation for an additional 10 minutes. The total weight of boron-iron-4PVPY surface-modified silica dispersion was 40 kg, the measured pH was 2.7-2.9, and the measured zeta potential was +45 mV to +50 mV.

The amounts of iron and 4PVPY can be varied in the boron-iron-4PVPY surface-modified colloidal silica particle by varying the concentrations of ferric nitrate and 4PVPY in the procedure described above.

Aqueous solutions of 4PVPY are bright orange colored. The addition of a bright orange solution of 4PVPY to the boron-iron surface-modified silica caused the disappearance of the orange color, producing a white dispersion of boron-iron-4PVPY surface-modified colloidal silica. The orange color disappeared due to the 4PVPY adsorbing on the surface of the boron-iron surface-modified silica.

In a second experiment the positively charged bright orange complex of iron-4PVPY was treated with boron surface-modified silica. The boron surface-modified silica had a zeta potential of (negative) −33 mV, whereas upon the addition of the iron-4PVPY complex solution to the boron surface-modified silica, the zeta potential changed from (negative) −33 mV to (positive) +39 mV, suggesting the formation of cationic silica particles of boron-iron-4PVPY surface-modified colloidal silica.

Procedure for Preparing Poly(2-vinylpyridine) (2PVPY) Modified Boron-Iron Surface-Modified Silica.

This procedure describes the preparation of poly(2-vinylpyridine) (2PVPY) modified boron-iron surface-modified silica with colloidal silica particles having an average particle diameter of 40 to 55 nanometers.

2PVPY modified boron-iron surface-modified silica was prepared according to the procedure described supra, with the exception that poly(4-vinylpyridine) was replaced with poly(2-vinylpyridine) for this procedure.

CMP Tools, Blanket Wafers, and Metrology

In the examples presented below, CMP experiments were run using the procedures and experimental conditions given below.

An EPO-222D (manufactured by Ebara Technologies Inc., 2-1 Hon Fujisawa 4-chome, Fujisawa-shi, 251, Japan) CMP tool was used for the polishing compositions of Examples 1 to 7. Polish conditions for the blanket wafer polishing studies in Examples 1 to 7 were: 60 second polish time per wafer; top-ring pressure 410 hPa; back-side pressure 100 hPa; turntable rotation 100 rpm; top-ring rotation 105 rpm; slurry flow 125 ml/min; using an IC1000/SUBA IV pad supplied by Rohm and Haas Electronic Materials. The polishing compositions of Examples 1 to 7 were used to polish CVD tungsten blanket wafers and thermal oxide dielectric blanket wafers. The blanket wafers, AMT-2853, were purchased from Advanced Materials Technology, Tokyo, Japan. For Examples 1 to 7, thermal oxide film thickness was measured with a KLA-Tencor F5x, manufactured by KLA-Tencor, 160 Rio Robles, San Jose, Calif. 95134. For Examples 1 to 7, metal film thickness was measured with a 4 Dimension four-point probe sheet resistance tool, manufactured by 4 Dimension Inc. Forty nine-point line scans were taken with the respective tools.

An IPEC-SpeedFam Avanti 472 (manufactured by SpeedFam IPEC, 305 North 54th Street, Chandler, Ariz. 85226) CMP tool was used for the polishing compositions of Examples 8 to 15. Polish conditions for the blanket wafer polishing studies in Examples 8 to 15 were: 60 second polish time per wafer; down force 7 psi; back pressure 0 psi; table speed 70 rpm; head speed 75 rpm; slurry flow 175 ml/min; using an IC1400 pad supplied by Rohm and Haas Electronic Materials. The polishing compositions of Examples 8 to 15 were used to polish CVD tungsten blanket wafers and PETEOS dielectric blanket wafers. The blanket wafers were purchased from Silicon Valley Microelectronics, 1150 Campbell Ave, Calif. 95126. The PETEOS wafers had a film thickness specification of 15,000 Å PETEOS. The CVD tungsten wafers had film stack thickness specifications of 8000 Å CVD tungsten/250 Å titanium/6300 Å thermal oxide. For Examples 8 to 15, PETEOS film thickness was measured with a Nanometrics, model, # 9200, manufactured by Nanometrics Inc, 1550 Buckeye, Milpitas, Calif. 95035-7418. For Examples 8 to 15, metal film thickness was measured with a ResMap CDE Model 168 four-point probe sheet resistance tool, manufactured by Creative Design Engineering, Inc, 20565 Alves Dr, Cupertino, Calif., 95014. This tool is a four-point probe sheet resistance tool. Twenty-five and forty nine-point polar scans were taken with the respective tools.

### Examples 1-7

### Comparative Example 1 and Examples 2-7

### Effect of Poly(4-vinylpyridine) (4PVPY) Concentration on Tungsten and Thermal Oxide Removal Rates, and Iron Contamination on Thermal Oxide

Comparative Example 1 and Examples 2-7 describes the effect of boron surface-modified silica, boron-iron surface-modified silica, and boron-iron-4PVPY surface-modified silica on tungsten and thermal oxide removal rates, and iron contamination on polished thermal oxide dielectric films.

The compositions of the polishing slurries for Comparative Example 1 and Examples 2-7 are described in Table 2. For Comparative Example 1 and Examples 2-7, the boron surface-modified silica was prepared according to the procedure described supra. For Examples 2-3, the boron-iron surface-modified silica were prepared according to the procedure described supra, with the exception that the amounts of iron were adjusted by varying the concentrations of ferric nitrate in the procedure described above. For Examples 4-7, the boron-iron-4PVPY surface-modified silica were prepared according to the procedure described supra, with the exception that the amounts of iron and 4PVPY were adjusted by varying the concentrations of ferric nitrate and 4PVPY in the procedure described above. REILLINE™ 410 poly(4-vinylpyridine) homopolymer was used as the 4PVPY for Examples 4-7. Each polishing slurry included 3 weight percent (Comparative Example 1) or 4 weight percent (Examples 2 to 7) hydrogen peroxide as an oxidant. The slurries in Comparative Example 1 and Examples 2 to 7 were used to polish tungsten and PETEOS wafers using methods described above. After the polishing and standard post CMP cleaning with dilute ammonia solution, iron ion concentration on the polished wafer surface was measured using a Total Reflection X-ray Fluorescence (TXRF) method. The data collected from TXRF is tabulated in Table 2.

### Discussions of Comparative Example 1 and Examples 2-7

Key results for Comparative Example 1 and Examples 2-7 are summarized in Table 2, which includes tungsten and thermal oxide removal rate data and W:TOx selectivity for wafers processed for seven slurries. As the data in this table indicate, compared to the experiment in Comparative Example 1, as the concentration of iron ions on the boron-iron-surface modified silica increased to 4.9 ppm (Example 2) and to 6.6 ppm (Example 3), the tungsten removal rates increased from 580 Å/min (Comparative Example 1) to 5543 Å/min (Example 2) and 6232 Å/min (Example 3), a 10.7-fold increase in the removal rate of tungsten. As expected, the iron contamination measured on the thermal oxide blanket wafer polished surface increased from 24 E10A/cm² (Comparative Example 1) to 138 E10A/cm² (Example 2) and to 205 E10A/cm² (Example 3). A comparison of Examples 2-3 with Examples 4-7 shows the effect of adding vinylpyridine polymer on the iron contamination. Clearly, as the concentration of vinylpyridine polymer increased, the iron contamination measured on the thermal oxide blanket wafer polished surface decreased from 205 E10A/cm² (Example 3) to 43 E10A/cm² (Example 6). Interestingly, as shown in Examples 4-7, the addition of vinylpyridine polymer decreased iron contamination on thermal oxide whilst maintaining elevated tungsten removal rates.

TABLE 2
Effect of Poly(4-vinylpyridine) on Tungsten and Thermal Oxide
Removal Rates, and Iron Contamination on Thermal Oxide.

| | Comparative | Example | Example | Example | Example | Example | Example |
|---|---|---|---|---|---|---|---|
| | Example 1 | 2 | 3 | 4 | 5 | 6 | 7 |
| pH | 2.8 | 4.4 | 3.9 | 3.3 | 3.3 | 3.4 | 3.3 |
| Boron surface-modified silica | 1.3 | 1.3 | 1.3 | 1.3 | 1.3 | 1.3 | 1.3 |
| (weight percent silica) | | | | | | | |
| Iron (ppm) | 0 | 4.9 | 6.6 | 8.5 | 13 | 6.6 | 8.5 |
| 4PVPY (ppm) | 0 | 0 | 0 | 42 | 42 | 58 | 58 |
| 4PVPY expressed as percent | 0 | 0 | 0 | 0.3 | 0.3 | 0.4 | 0.4 |
| by weight of boron-iron- | | | | | | | |
| surface-modified silica | | | | | | | |
| Water | Balance | Balance | Balance | Balance | Balance | Balance | Balance |
| Nitric acid (ppm) for pH | 124 | 0 | 0 | 24 | 24 | 34 | 34 |
| adjustment | | | | | | | |
| Hydrogen peroxide | 3 | 4 | 4 | 4 | 4 | 4 | 4 |
| (weight percent) | | | | | | | |
| Tungsten Removal Rate | 580 | 5543 | 6232 | 5775 | 5720 | 5670 | 5657 |
| (Å/min) | | | | | | | |
| Thermal Oxide Removal | 124 | 50 | 93 | 188 | 118 | 74 | 74 |
| Rate (Å/min) | | | | | | | |
| W:TOx Sel | 4.7 | 111 | 67 | 31 | 48 | 77 | 76 |
| Iron Contamination on | 24 | 138 | 205 | 46 | 91 | 43 | 69 |
| Thermal Oxide (E10A/cm²) | | | | | | | |

### Examples 8-13

### Comparative Examples 8-9 and Examples 10-13

### Effect of Poly(4-vinylpyridine) Concentration on the PETEOS Removal Rates and Tungsten-to-PETEOS Selectivity in the Presence of Fumed Silica as Co-Abrasive

The compositions of the polishing slurries for Comparative Examples 8-9 and Examples 10-13 are described in Table 3. In order to evaluate the effect of poly(4-vinylpyridine) (4PVPY) on tungsten and PETEOS substrates, six slurry samples were prepared, two slurries with no 4PVPY as shown in Comparative Examples 8 and 9, and the remaining four slurry samples with different concentration as shown in Examples 10-13 in Table 3. All examples also contained 0.3 weight percent of Aerosil® OX 50 fumed silica particles (particle size 0.25 micron) to increase tungsten removal rates. Each polishing slurry included 3 weight percent hydrogen peroxide as an oxidant. Poly(4-vinylpyridine) supplied by Sigma-Aldrich was used for Examples 10-13.

Discussions of Comparative Examples 8-9 and Examples 10-13

Key results for Comparative Examples 8-9 and Examples 10-13 are summarized in Table 3, which includes tungsten and PETEOS removal rate data and W:PETEOS selectivity for wafers processed for six slurries. As the data in this table indicates, compared to the experiments in Comparative Examples 8 and 9, as the concentration of 4PVPY increased from zero to 625 ppm in the slurry, the PETEOS removal rates decreased dramatically from 456 and 958 Å/min for the Comparative Examples 8-9 to 9 Å/min at 625 ppm 4PVPY (Example 13), thus increasing the W:PETEOS selectivity from 7.9 (Comparative Example 9) to 132 (Example 13). The data also suggest that as the 4PVPY concentration increased, tungsten removal rate also decreased, thus 4PVPY can be used to vary both tungsten and PETEOS dielectric removal rates in the presence of fumed silica co-abrasive.

TABLE 3
Effect of Poly(4-vinylpyridine) on Tungsten, PETEOS
Removal Rates, and Tungsten to PETEOS Selectivity.

| | Comparative | Comparative | | | | |
|---|---|---|---|---|---|---|
| | Example 8 | Example 9 | Example | Example | Example | Example |
| | No 4PVPY | No 4PVPY | 10 | 11 | 12 | 13 |
| pH | 2.5 | 3.1 | 2.7 | 2.8 | 2.8 | 2.4 |
| Boron surface-modified silica | 1.2 | 1.2 | 1.2 | 1.2 | 1.2 | 1.2 |
| (weight percent silica) | | | | | | |
| Iron (ppm) | 25 | 25 | 50 | 35 | 40 | 25 |
| 4PVPY (ppm) | 0 | 0 | 125 | 175 | 375 | 625 |
| 4PVPY expressed as percent | 0 | 0 | 1.0 | 1.5 | 3.1 | 5.2 |
| by weight of boron-iron- | | | | | | |
| surface-modified silica | | | | | | |
| Fumed silica | 0.3 | 0.3 | 0.3 | 0.3 | 0.3 | 0.3 |
| (weight percent silica) | | | | | | |
| Water | Balance | Balance | Balance | Balance | Balance | Balance |
| Surfynol ® 104 (ppm) | 700 | 900 | 700 | 700 | 700 | 700 |
| SDS (ppm) | 250 | 25 | 0 | 0 | 0 | 0 |
| Nitric acid (ppm) for pH | <525 | <525 | <525 | <525 | <525 | <525 |
| adjustment | | | | | | |
| Hydrogen peroxide | 3 | 3 | 3 | 3 | 3 | 3 |
| (weight percent) | | | | | | |
| Tungsten Removal Rate | 7446 | 7546 | 7336 | 5613 | 1308 | 1186 |
| (Å/min) | | | | | | |
| PETEOS Removal Rate | 456 | 958 | 293 | 213 | 48 | 9 |
| (Å/min) | | | | | | |
| W:PETEOS Sel | 16 | 7.9 | 25 | 26 | 27 | 132 |

### Examples 14-15

### Examples 14-15

### Comparison of Poly(4-vinylpyridine) with Poly(2-vinylpyridine) on Tungsten and PETEOS Removal Rates

The compositions of the polishing slurries for Examples 14-15 are described in Table 4. In order to compare the difference between poly(4-vinylpyridine) (4PVPY) and poly(2-vinylpyridine) (2PVPY) on tungsten and PETEOS removal rates, two slurry samples were prepared: one slurry with 4PVPY as shown in Example 14 and the second sample with 2PVPY a shown in Example 15. Poly(4-vinylpyridine) supplied by Sigma-Aldrich was used for Example 14. Poly(2-vinylpyridine) supplied by Sigma-Aldrich was used for Example 15.

Both polishing slurries included 3 weight percent hydrogen peroxide as an oxidant. The results are summarized in Table 4. Clearly, isomeric polymers such as 4PVPY, and 2PVPY performed comparably from the standpoint of tungsten and PETEOS dielectric removal rates.

TABLE 4
Effect of Isomerism on the Tungsten Removal Rates,
Comparison of Poly(4-vinylpyridine), and Poly(2-vinylpyridine)
on Tungsten to PETEOS selectivity.

| | Example 14 | Example 15 |
|---|---|---|
| | 4PVPY | 2PVPY |
| pH | 2.9 | 2.8 |
| Boron surface-modified silica | 1.2 | 1.2 |
| (weight percent silica) | | |
| Iron (ppm) | 35 | 35 |
| PVPY (ppm) | 188 of 4PVPY | 175 of 2PVPY |
| PVPY expressed as percent by weight | 1.6 | 1.5 |
| of boron-iron-surface-modified | | |
| silica | | |
| Fumed silica (weight percent silica) | 0.3 | 0.3 |
| Water | Balance | Balance |
| Surfynol ® 104 (ppm) | 700 | 700 |
| Nitric acid (ppm) for pH adjustment | <525 | <525 |
| Hydrogen peroxide (weight percent) | 3 | 3 |
| Tungsten Removal Rate (Å/min) | 5835 | 5613 |
| PETEOS Removal Rate (Å/min) | 156 | 213 |
| W:PETEOS Sel | 37 | 26 |

While the invention has been described in detail and with reference to specific examples thereof, it will be apparent to one skilled in the art that various changes and modifications can be made therein without departing from the spirit and scope thereof.

1. A chemical-mechanical polishing composition for substrates containing at least one metal and at least one dielectric material comprising:
a) a stabilizer-Fenton's reaction metal-vinyl pyridine polymer-surface-modified abrasive; and
b) an oxidizing agent.

2. The composition of claim 1 further comprising c) water.

3. The composition of claim 1 wherein the stabilizer is a compound comprised of an element selected from the group consisting of boron, aluminum, tungsten, and titanium.

4. The composition of claim 1 wherein the Fenton's reaction metal is selected from the group consisting of copper, iron, manganese, titanium, tungsten, silver, and vanadium.

5. The composition of claim 4 wherein the Fenton's reaction metal is iron.

6. The composition of claim 1 wherein the vinyl pyridine polymer is selected from the group consisting of poly(2-vinyl pyridine) and poly(4-vinyl pyridine).

7. The composition of claim 1 wherein the pH of the composition ranges from 1 to 5.

8. The composition of claim 1 wherein the oxidizing agent is a peroxide-type oxidizing agent.

9. The composition of claim 8 wherein the peroxide-type oxidizing agent is hydrogen peroxide.

10. The composition of claim 1 wherein the abrasive is a stabilizer-Fenton's reaction metal-vinyl pyridine polymer-surface-modified silica.

11. The composition of claim 10 wherein the silica is a boron-iron-poly(2- or 4-vinylpyridine)-surface-modified silica.

12. The composition of claim 1 further comprising c) a fumed co-abrasive.

13. A method of polishing comprising the steps of:
A) placing a substrate in contact with a polishing pad;
B) delivering a polishing composition comprising:
a) a stabilizer-Fenton's reaction metal-vinyl pyridine polymer-surface-modified abrasive; and
b) an oxidizing agent; and
C) polishing the substrate with the polishing composition.

14. The method of claim 13 wherein the composition further comprises c) water.

15. The method of claim 13 wherein the stabilizer in the composition is a compound comprised of an element selected from the group consisting of boron, aluminum, tungsten, and titanium.

16. The method of claim 13 wherein the Fenton's reaction metal in the composition is selected from the group consisting of copper, iron, manganese, titanium, tungsten, silver, and vanadium.

17. The method of claim 16 wherein the Fenton's reaction metal in the composition is iron.

18. The method of claim 13 wherein the vinyl pyridine polymer in the composition is selected from the group consisting of poly(2-vinyl pyridine) and poly(4-vinyl pyridine).

19. The method of claim 13 wherein the pH of the composition ranges from 1 to 5.

20. The method of claim 13 wherein the oxidizing agent in the composition is a peroxide-type oxidizing agent.

21. The method of claim 8 wherein the peroxide-type oxidizing agent in the composition is hydrogen peroxide.

22. The method of claim 13 wherein the abrasive in the composition is a stabilizer-Fenton's reaction metal-vinyl pyridine polymer-surface-modified silica.

23. The method of claim 22 wherein the silica in the composition is a boron-iron-poly(2- or 4-vinylpyridine)-surface-modified silica.

24. The method of claim 13 wherein the composition further comprises c) a fumed co-abrasive.
